(19) United States
(12) Patent Application Publication
(10) Pub. No.: US 2004/0135185 A1
(43) Pub. Date: Jul. 15, 2004

(54) Semiconductor device and method of manufacturing the same

(76) Inventor: Moto Yabuki, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/682,113

(22) Filed: Oct. 10, 2003

(30) Foreign Application Priority Data
Oct. 11, 2002 (JP) 2002-298500

(51) Int. Cl. H01L 27/108; H01L 21/8234

(52) U.S. Cl. 257/296; 438/238; 257/306; 438/244

(57) ABSTRACT

Disclosed is a semiconductor device comprising a semiconductor substrate, a capacitor provided above the semiconductor substrate and including a bottom electrode, a top electrode, and a dielectric film provided between the top electrode and the bottom electrode, an insulating region surrounding the capacitor and having a first hole which extends in a vertical direction and reaches the top electrode and a second hole which extends in the vertical direction and is spaced away from the capacitor, and a first wiring connected to the top electrode and including a first conductive portion formed in the first hole and a second conductive portion formed in the second hole, the first wiring having a barrier metal film between the insulating region and the first conductive portion and having no barrier metal film between the insulating region and the second conductive portion.

### CROSS-REFERENCE TO RELATED APPLICATIONS

This application is based upon and claims the benefit of priority from the prior Japanese Patent Application No. 2002-298500, filed Oct. 11, 2002, the entire contents of which are incorporated herein by reference.

### BACKGROUND OF THE INVENTION

1. Field of the Invention

The present invention relates to a semiconductor device having a capacitor and a method of manufacturing the same.

2. Description of the Related Art

Research and development is conducted on nonvolatile memories (FeRAMs) using a ferroelectric film such as a PZT film (Pb(Zr,Ti)O₃ film) for a dielectric film of a capacitor.

A prior art method of manufacturing a ferroelectric memory will now be described with reference to FIGS. 3A to 3D.

Referring first to FIG. 3A, a MIS transistor 12, an interlayer insulation film 13, a W plug 14, a silicon nitride film 15 and a silicon oxide film 16 are formed on a semiconductor substrate 11. A ferroelectric capacitor including a bottom electrode 21, a ferroelectric film 22 and a top electrode 23 is formed on the silicon oxide film 16. The bottom and top electrodes 21 and 23 are formed of a platinum (Pt) film, an iridium (Ir) film, an IrO₂ film or the like. The ferroelectric film 22 is formed of a PZT film or the like. An interlayer insulation film 24 is formed on the entire surface of the resultant structure and patterned to form a connecting hole 31 that reaches the top electrode 23, a connecting hole 32 that reaches the bottom electrode 21 and a connecting hole 33 that reaches the W plug 14.

Referring now to FIG. 3B, a barrier metal film such as TIN and an Al film are deposited in sequence. By performing processing such as CMP, a barrier metal film 34a and an Al film 35a are formed in the connecting hole 31, a barrier metal film 34b and an Al film 35b are formed in the connecting hole 32 and a barrier metal film 34c and an Al film 35c are formed in the connecting hole 33. The barrier metal films prevent the Al films from being alloyed with the films (Pt film, Ir film, etc.) used for the bottom and top electrodes 21 and 23.

Referring now to FIG. 3C, a silicon oxide film 36 is deposited on the entire surface of the resultant structure and patterned to form trenches 37 and 38. An Al film 39a is formed in the trench 37 and an Al film 39b is formed in the trench 38, as shown in FIG. 3D.

In the above steps, a wiring including the Al films 35a, 39a and 35c is connected to the top electrode 23 of the capacitor, and a wiring including the Al films 35b and 39b is connected to the bottom electrode 21 of the capacitor.

In the foregoing prior art manufacturing method, however, the barrier metal and Al films are formed in the connecting hole 33 as well as the connecting holes 31 and 32. The connecting hole 33 is deeper than the connecting holes 31 and 32 and the diameter of the hole 33 is generally smaller than that of each of the holes 31 and 32. If, therefore, the semiconductor device is microfabricated, the barrier metal and Al films become difficult to completely bury in the connecting hole 33 and thus a void or the like easily occurs in the Al film. Consequently, the wiring greatly deteriorates in characteristic and reliability.

Jpn. Pat. Appln. KOKAI Publication No. 2001-102538 proposes a technique of burying metal in a contact hole and a trench at once in a ferroelectric memory. If, however, a barrier metal film is used in the structure proposed in the Publication, the barrier metal film and metal film are difficult to completely bury in a deep contact hole (connecting hole), when a semiconductor device is microfabricated. For this reason, a wiring greatly deteriorates in characteristic and reliability.

According to the prior art ferroelectric memories described above, the barrier metal film and Al film are formed even in a connecting hole in a region that separates from the capacitor. Thus, the Al film becomes difficult to bury in the connecting hole and the wiring greatly deteriorates in characteristic and reliability.

### BRIEF SUMMARY OF THE INVENTION

According to a first aspect of the present invention, there is provided a semiconductor device comprising: a semiconductor substrate; a capacitor provided above the semiconductor substrate and including a bottom electrode, a top electrode, and a dielectric film provided between the top electrode and the bottom electrode; an insulating region surrounding the capacitor and having a first hole which extends in a vertical direction and reaches the top electrode and a second hole which extends in the vertical direction and is spaced away from the capacitor; and a first wiring connected to the top electrode and including a first conductive portion formed in the first hole and a second conductive portion formed in the second hole, the first wiring having a barrier metal film between the insulating region and the first conductive portion and having no barrier metal film between the insulating region and the second conductive portion.

According to a second aspect of the present invention, there is provided a method of manufacturing a semiconductor device comprising: forming a capacitor above a semiconductor substrate, the capacitor being surrounded with an insulating region and including a bottom electrode, a top electrode and a dielectric film provided between the top electrode and the bottom electrode; and forming a first wiring connected to the top electrode, forming the first wiring including: removing part of the insulating region to form a first hole which extends in a vertical direction and reaches the top electrode; forming a barrier metal film in the first hole; forming a first conductive portion in the first hole in which the barrier metal film is formed; removing part of the insulating region to form a second hole which extends in the vertical direction and is spaced away from the capacitor; and forming a second conductive portion in the second hole without forming a barrier metal film in the second hole.

### BRIEF DESCRIPTION OF THE SEVERAL VIEWS OF THE DRAWING

FIGS. 1A to 1D are sectional views schematically showing a method of manufacturing a semiconductor device according to a first embodiment of the present invention;

FIGS. 2A to 2D are sectional views schematically showing a method of manufacturing a semiconductor device according to a second embodiment of the present invention; and

FIGS. 3A to 3D are sectional views schematically showing a method of manufacturing a prior art semiconductor device.

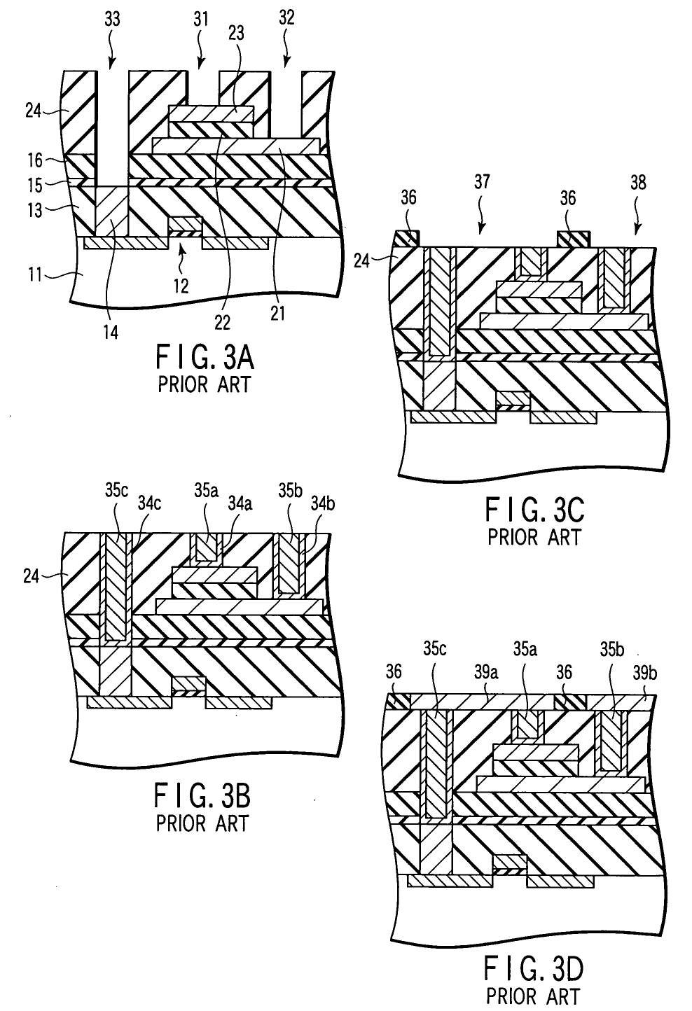

### DETAILED DESCRIPTION OF THE INVENTION

Embodiments of the present invention will now be described with reference to the accompanying drawings.

### FIRST EMBODIMENT

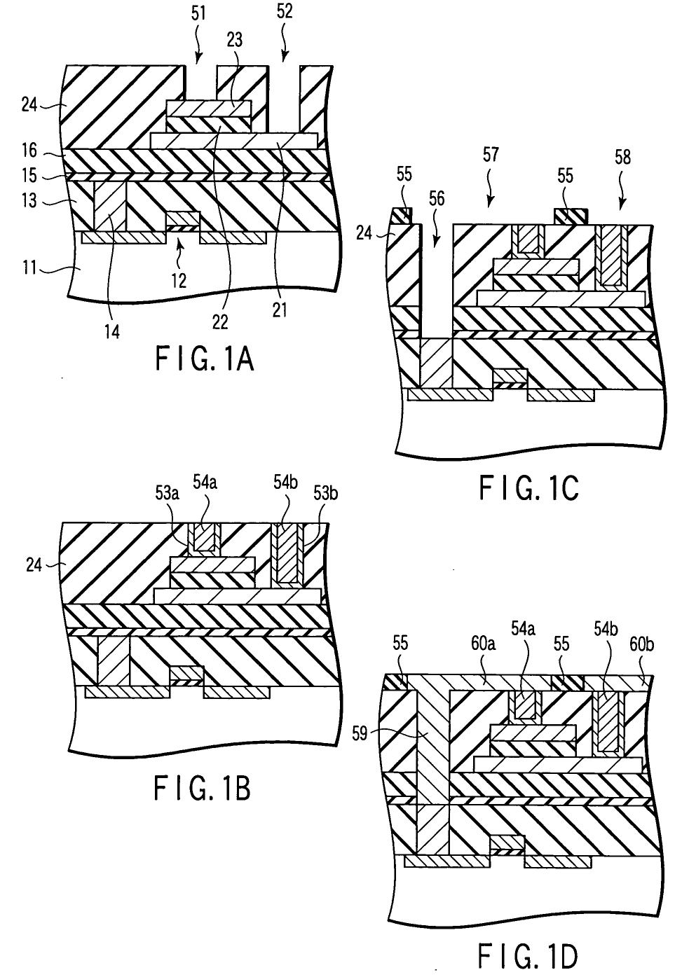

FIGS. 1A to 1D are sectional views schematically showing a method of manufacturing a semiconductor device (ferroelectric memory) according to a first embodiment of the present invention.

Referring first to FIG. 1A, a MIS transistor 12 is formed on a semiconductor substrate 11 such as a silicon substrate. An interlayer insulation film 13 such as a silicon oxide film (SiO₂ film) is formed on the entire surface of the resultant structure. A connecting hole is opened in the interlayer insulation film 13 to reach the source or drain of the MIS transistor 12 and filled with a W plug 14. A silicon nitride film (SiN film) 15 and a silicon oxide film (SiO₂ film) 16 are formed on the entire surface of the resultant structure.

A ferroelectric capacitor is formed on the silicon oxide film 16 and includes a bottom electrode 21, a ferroelectric film 22 formed on the bottom electrode 21 and a top electrode 23 formed on the ferroelectric film 22. The bottom and top electrodes 21 and 23 are formed of a platinum (Pt) film, an iridium (Ir) film, an IrO₂ film or the like. The ferroelectric film 22 is formed of a PZT film (Pb(Zr,Ti)O₃ film) or the like.

An interlayer insulation film 24 such as a silicon oxide film is formed on a region including the capacitor. As a result, the capacitor is surrounded with an insulating region including the silicon oxide film 16 and interlayer insulation film 24. The interlayer insulation film 24 is patterned by photolithography and RIE to form a connecting hole 51 that reaches the top electrode 23 and a connecting hole 52 that reaches the bottom electrode 21.

Referring now to FIG. 1B, a barrier metal film and a metal film are deposited in sequence on the entire surface of the structure including the connecting holes 51 and 52. The barrier metal film is formed of a TiN film, a NbN film, a TaN film, a TaAlN film or a stacked structure of these films. The metal film is formed of an Al film. An unnecessary portion is removed from the barrier metal film and metal film by CMP to leave the barrier metal film 53a and metal film 54a (conductive portion) in the connecting hole 51 and leave the barrier metal film 53b and metal film 54b (conductive portion) in the connecting hole 52. In order to bury the metal films 54a and 54b in their respective connecting holes 51 and 52 by reflow of Al, a liner film is formed in advance on the barrier metal films 53a and 53b. The liner film differs from the barrier metal films 53a and 53b and is formed of, e.g., a Ti film or a Nb film.

Referring now to FIG. 1C, a silicon oxide film 55 is deposited as an insulating film on the entire surface of the resultant structure. The silicon oxide film 55, interlayer insulation film 24, silicon oxide film 16 and silicon nitride film 15 are patterned by photolithography and RIE. Thus, a connecting hole 56 that reaches the W plug 14 is formed and so are trenches 57 and 58.

Referring now to FIG. 1D, an Al film is formed as a metal film on the entire surface of the resultant structure. An unnecessary portion is removed from the metal film by CMP. Thus, a conductive portion of a metal film 59 is formed in the connecting hole 56, a conductive portion of a metal film 60a is formed in the trench 57 and a conductive portion of a metal film 60b is formed in the trench 58. To form the metal films 59, 60a and 60b by reflow of Al, a liner film is formed in advance. The liner film differs from the barrier metal films 53a and 53b and is formed of, e.g., a Ti film or a Nb film.

The top electrode 23 of the capacitor and the W plug 14 connected to the source or drain of the MIS transistor 12 are connected to each other through a wiring including the conductive portion 54a extending in the vertical direction, the conductive portion 60a extending in the horizontal direction, and the conductive portion 59 extending in the vertical direction. The bottom electrode 21 of the capacitor is connected to a wiring including the conductive portion 54b extending in the vertical direction and the conductive portion 60b extending in the horizontal direction.

According to the first embodiment described above, the connecting holes 51 and 52 are formed to reach the bottom and top electrodes 21 and 23, then the barrier metal film and metal film (Al film) are formed in the connecting holes 51 and 52, and then the connecting hole 56 is formed to reach the W plug 14. Accordingly, no barrier metal film is formed in the connecting hole 56. The barrier metal film prevents the metal film (Al film, etc.) serving as a wiring film from being alloyed with the metal films (Pt film, Ir film, etc.) used for the bottom and top electrodes 21 and 23. No problems therefore occur even though no barrier metal film is formed in the connecting hole 56. According to the first embodiment, therefore, the metal film serving as a wiring film and the metal films used for the bottom and top electrodes can be prevented from being alloyed with each other, and the metal film can reliably and easily be buried into the connecting hole that separates from the capacitor. Consequently, even though the semiconductor device is microfabricated, the wiring can be improved in characteristic and reliability.

### SECOND EMBODIMENT

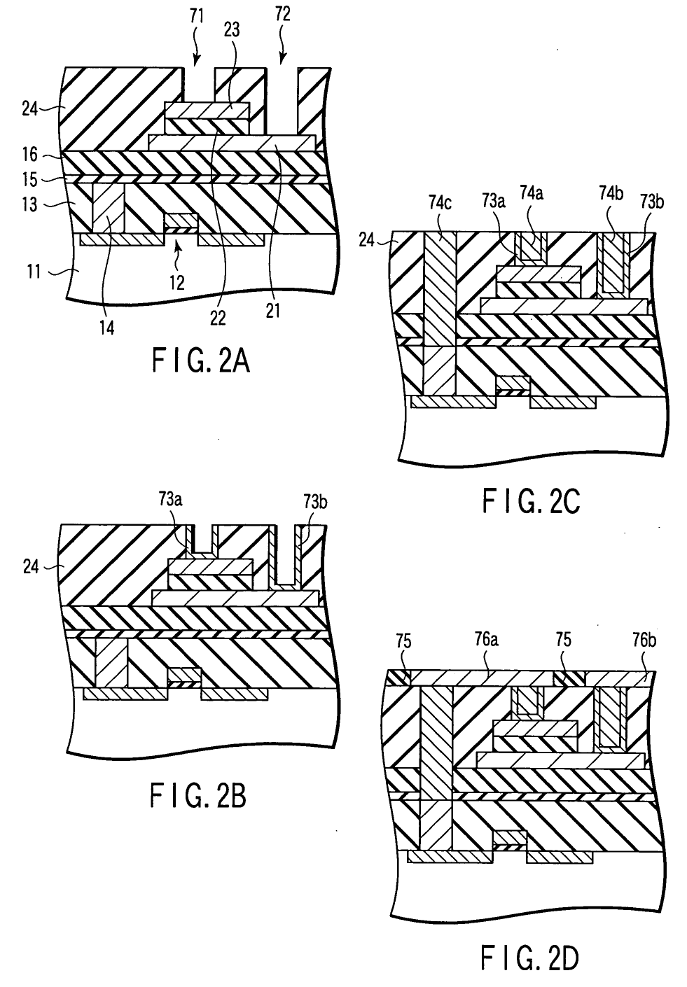

FIGS. 2A to 2D are sectional views schematically showing a method of manufacturing a semiconductor device (ferroelectric memory) according to a second embodiment of the present invention. The components corresponding to those shown in FIGS. 1A to 1D are indicated by the same reference numerals and their detailed descriptions are omitted.

The fundamental step shown in FIG. 2A is the same as that shown in FIG. 1A. More specifically, a ferroelectric capacitor including a bottom electrode 21, a ferroelectric film 22 and a top electrode 23 is formed and then an interlayer insulation film 24 is formed to cover the ferroelectric capacitor. The interlayer insulation film 24 is patterned by photolithography and RIE to form a connecting hole 71 that reaches the top electrode 23 and a connecting hole 72 that reaches the bottom electrode 21.

Referring now to FIG. 2B, a barrier metal film is deposited on the entire surface of the structure including the connecting holes 71 and 72. The barrier metal film is formed of a TiN film, a NbN film, a TaN film, a TaAlN film or a stacked structure of these films. An unnecessary portion is removed from the barrier metal film by CMP to leave the barrier metal 73a along the inner surface of the connecting hole 71 and leave a barrier metal film 73b along the inner surface of the connecting hole 72.

Referring now to FIG. 2C, the interlayer insulation film 24, silicon oxide film 16 and silicon nitride film 15 are patterned by photolithography and RIE to form a connecting hole that reaches a W plug 14. A metal film (Al film) is deposited on the entire surface of the resultant structure. An unnecessary portion is removed from the metal film by CMP to leave metal films 74a, 74b and 74c as conductive portions in the connecting holes 71 and 72 and the connecting hole that reaches the W plug 14, respectively. In order to form the metal films 74a, 74b and 74c in the connecting holes by reflow of Al, the same liner film as that in the first embodiment is formed in advance.

Referring now to FIG. 2D, a silicon oxide film 75 is deposited on the entire surface of the resultant structure as an insulating film. The silicon oxide film 75 is patterned by photolithography and RIE to form a trench that reaches the metal films 74a and 74c and a trench that reaches the metal film 74b. After that, an Al film is formed on the entire surface of the resultant structure as a metal film. An unnecessary portion is removed from the metal film by CMP to form a conductive portion of a metal film 76a and a conductive portion of a metal film 76b in their respective trenches. In order to form the metal films 76a and 76b by reflow of aluminum, the same liner film as that in the first embodiment is formed in advance.

The top electrode 23 of the capacitor and the W plug 14 connected to the source or drain of the MIS transistor 12 are connected to each other through a wiring including the conductive portion 74a extending in the vertical direction, the conductive portion 76a extending in the horizontal direction and the conductive portion 74c extending in the vertical direction. The bottom electrode 21 of the capacitor is connected to a wiring including the conductive portion 74b extending in the vertical direction and the conductive portion 76b extending in the horizontal direction.

In the second embodiment described above, too, no barrier metal film is formed in the connecting hole that reaches the W plug 14. Accordingly, as in the first embodiment, the metal film serving as a wiring film is prevented from being alloyed with the metal films used for the bottom and top electrodes, and the metal film can reliably and easily be buried into the connecting hole that separates from the capacitor. Consequently, even though the semiconductor device is microfabricated, the wiring can be improved in characteristic and reliability.

In the foregoing second embodiment, the metal films 74a, 74b and 74c are formed in the connecting holes in the same step. However, these metal films can be formed as follows: First, the barrier metal films 73a and 73b are formed in the step shown in FIG. 2B and then the metal films 74a and 74b are formed. After that, a connecting hole that reaches the W plug 14 is formed and the metal film 74c is formed in the connecting hole.

In the foregoing second embodiment, the metal films 76a and 76b are buried in the trenches formed in the silicon oxide film 75 in the step shown in FIG. 2D. However, after the step shown in FIG. 2C, a metal film can be formed in the entire surface of the structure and then patterned by RIE or the like to form the metal films 76a and 76b.

In the foregoing first and second embodiments, a conductive portion connected to the bottom electrode 21 is provided on the upper side of the bottom electrode. However, the conductive portion can be provided on the lower side of the bottom electrode (a so-called COP structure).

In the foregoing first and second embodiments, a conductive portion (conductive portion 59 in FIGS. 1A to 1D and conductive portion 74c in FIGS. 2A to 2D) is connected to the source or drain of the MIS transistor 12 through the W plug 14. However, the conductive portion can be connected to the source or drain without providing the W plug 14.

In the foregoing first and second embodiments, the Al film is used as a metal film to be formed in the connecting hole or the trench. However, the Al film can be replaced with a Cu film or a W film.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a capacitor provided above the semiconductor substrate and including a bottom electrode, a top electrode, and a dielectric film provided between the top electrode and the bottom electrode;
an insulating region surrounding the capacitor and having a first hole which extends in a vertical direction and reaches the top electrode and a second hole which extends in the vertical direction and is spaced away from the capacitor; and
a first wiring connected to the top electrode and including a first conductive portion formed in the first hole and a second conductive portion formed in the second hole, the first wiring having a barrier metal film between the insulating region and the first conductive portion and having no barrier metal film between the insulating region and the second conductive portion.

2. The semiconductor device according to claim 1, wherein the first wiring includes a third conductive portion formed on the insulating region and connecting the first conductive portion and the second conductive portion.

3. The semiconductor device according to claim 1, wherein the insulating region has a third hole extending in the vertical direction and reaching the bottom electrode, and
wherein the semiconductor device further comprises a second wiring including a third conductive portion formed in the third hole, the second wiring having a barrier metal film between the insulating region and the third conductive portion.

4. The semiconductor device according to claim 1, further comprising a transistor provided on the semiconductor substrate and electrically connected to the first wiring.

5. The semiconductor device according to claim 1, wherein the second hole has a depth greater than that of the first hole.

6. The semiconductor device according to claim 1, wherein the barrier metal film between the insulating region and the first conductive portion includes at least one of a TiN film, an NbN film, a TaN film and a TaAlN film.

7. The semiconductor device according to claim 1, wherein the first conductive portion and the second conductive portion contain aluminum.

8. The semiconductor device according to claim 1, wherein the top electrode contains at least one of Pt and Ir.

9. The semiconductor device according to claim 1, wherein the dielectric film includes a ferroelectric film.

10. A method of manufacturing a semiconductor device comprising:
forming a capacitor above a semiconductor substrate, the capacitor being surrounded with an insulating region and including a bottom electrode, a top electrode and a dielectric film provided between the top electrode and the bottom electrode; and
forming a first wiring connected to the top electrode,
forming the first wiring including:
removing part of the insulating region to form a first hole which extends in a vertical direction and reaches the top electrode;
forming a barrier metal film in the first hole;
forming a first conductive portion in the first hole in which the barrier metal film is formed;
removing part of the insulating region to form a second hole which extends in the vertical direction and is spaced away from the capacitor; and
forming a second conductive portion in the second hole without forming a barrier metal film in the second hole.

11. The method according to claim 10, wherein forming the second conductive portion includes forming a third conductive portion on the insulating region, the third conductive portion connecting the first conductive portion and the second conductive portion.

12. The method according to claim 10, wherein forming the first wiring includes forming a third conductive portion after the first conductive portion and the second conductive portion are formed, the third conductive portion connecting the first conductive portion and the second conductive portion.

13. The method according to claim 10, wherein forming the first conductive portion and forming the second conductive portion are performed in a same process.

14. The method according to claim 10, wherein forming the first wiring includes forming a second wiring connected to the bottom electrode.
